(19) United States
(12) Patent Application Publication
(10) Pub. No.: US 2025/0290967 A1
(43) Pub. Date: Sep. 18, 2025

(54) MEASURING METHOD AND MANUFACTURING METHOD

(71) Applicant: FUJI ELECTRIC CO., LTD., Kawasaki-shi (JP)

(72) Inventors: Yuki SAWA, Matsumoto-city (JP); Toru AJIKI, Matsumoto-city (JP); Yoshiki TAKESAKO, Matsumoto-city (JP)

(73) Assignee: FUJI ELECTRIC CO., LTD., Kawasaki-shi (JP)

(21) Appl. No.: 19/041,400

(22) Filed: Jan. 30, 2025

(30) Foreign Application Priority Data
Mar. 12, 2024 (JP) 2024-038016

(51) Int. Cl. G01R 31/26; H01L 21/66

(52) U.S. Cl. CPC G01R 31/2607; H01L 22/14

(57) ABSTRACT

A method of measuring a characteristic of a semiconductor device that is a first metal-oxide-semiconductor (MOS) transistor using a stage. The method includes: obtaining a first correlation between a characteristic, and a withstand voltage, of each of a plurality of second MOS transistors, the characteristic being measured under a condition that, for each second MOS transistor, a contact resistance between the stage, at which the second MOS transistor is placed, and an electrode of the second MOS transistor, is equal to or lower than a predetermined rate of an on-resistance of the second MOS transistor; measuring a withstand voltage of the first MOS transistor when the first MOS transistor is off; and outputting the characteristic of the first MOS transistor, using the first correlation and the measured withstand voltage of the first MOS transistor.

### CROSS-REFERENCE TO RELATED APPLICATIONS

The present application claims priority pursuant to 35 U.S.C. § 119 from Japanese patent application number 2024-038016 filed on Mar. 12, 2024, the entire disclosure of which is hereby incorporated by reference herein.

### BACKGROUND

### Technical Field

The present disclosure relates to a measuring method and a manufacturing method.

### Description of the Related Art

When metal-oxide-semiconductor (MOS) transistors are manufactured, the resistance in an ON state (hereafter referred to as on-resistance) may be measured among various characteristics (for example, Japanese Patent Application Publication No. 2005-055231).

In general, a measurement of the on-resistance of such a MOS transistor is performed, assuming the state of actual use, such that a current with a set value is passed in the state where the MOS transistor is on. In other words, the larger the current is to be passed, the larger the current value during the measurement is set.

Thus, particularly in measurements of the MOS transistors in which a large current is passed, measurement results may vary due to the contact resistance between the electrode of such a MOS transistor and the probe and/or stage of the measuring device.

### SUMMARY

An aspect of the present disclosure is a method of measuring a characteristic of a semiconductor device that is a first metal-oxide-semiconductor (MOS) transistor using a stage, the method comprising: obtaining a first correlation between a characteristic, and a withstand voltage, of each of a plurality of second MOS transistors, the characteristic being measured under a condition that a contact resistance between the stage, at which said each second MOS transistor is placed, and an electrode of said each second MOS transistor, is equal to or lower than a predetermined rate of an on-resistance of said each second MOS transistor; measuring a withstand voltage of the first MOS transistor when the first MOS transistor is off; and outputting the characteristic of the first MOS transistor, using the first correlation and the measured withstand voltage of the first MOS transistor.

Another aspect of the present disclosure is a method of measuring a characteristic of a semiconductor device that is a first metal-oxide-semiconductor (MOS) transistor using a stage, the method comprising: obtaining a correlation between a characteristic, and a threshold voltage, of each of a plurality of second MOS transistors, the characteristic being measured under a condition that a contact resistance between the stage, at which said each second MOS transistor is placed, and an electrode of said each second MOS transistor, is equal to or lower than a predetermined rate f an on-resistance of said each second MOS transistor; measuring a threshold voltage of the first MOS transistor; and outputting the characteristic of the first MOS transistor, using the obtained correlation and the measured threshold voltage of the first MOS transistor. Other features of the present disclosure will become apparent from the description in the present specification and the accompanying drawings.

### BRIEF DESCRIPTION OF THE DRAWINGS

FIG. 1 is a diagram illustrating a measuring system 1 in a measuring method according to a first embodiment.

FIG. 2A is a diagram for explaining a metal-oxide-semiconductor (MOS) transistor T1 to be measured by a measuring method according to a first embodiment.

FIG. 2B is a diagram for explaining a MOS transistor T1 to be measured by a measuring method according to a first embodiment.

FIG. 3 is a diagram for explaining a MOS transistor T1 to be measured by a measuring method according to a first embodiment.

FIG. 4 is a diagram for explaining a method of measuring a withstand voltage Vdss according to a first embodiment.

FIG. 5 is a diagram for explaining a method of measuring an on-voltage Von according to a first embodiment.

FIG. 6 illustrates a correlation CR1 used in a measuring method according to a first embodiment.

FIG. 7 is a flowchart for explaining a measuring method according to a first embodiment.

FIG. 8 is a diagram for explaining classification results for a plurality of MOS transistors T1 according to a first embodiment.

FIG. 9 is a flow chart for explaining a method of manufacturing a semiconductor module 3 including a MOS transistor T1 classified by a measuring method according to a first embodiment.

FIG. 10 is a diagram for explaining a semiconductor module 3 including a MOS transistor T1 classified by a measuring method according to a first embodiment.

FIG. 11 is a diagram for explaining a correlation CR2 used in a measuring method according to a second embodiment.

### DETAILED DESCRIPTION

At least following matters will become apparent from the descriptions of the present specification and the accompanying drawings.

### First Embodiment

### <<Measuring Method>>

A method of measuring a semiconductor device according to an embodiment of the present disclosure will be described. The measuring method according to an embodiment of the present disclosure is a method of measuring the characteristic corresponding to an on-resistance Ron of the MOS transistor T1, which is a semiconductor device, in a method of manufacturing the semiconductor device.

In an embodiment of the present disclosure, the “characteristic corresponding to the on-resistance Ron” is an on-voltage Von. The “on-voltage Von” is the drain-source voltage when a predetermined current Ion flows while a predetermined voltage Vgs is being applied between the gate and the source of the MOS transistor T1 to be measured.

Note that the “characteristic corresponding to the on-resistance Ron” is not limited to the on-voltage Von, but may be the on-resistance Ron. The “on-resistance Ron” is a value obtained by multiplying the on-voltage Von by the above-described current Ion.

Further, the MOS transistor T1, which is to be measured as to the “characteristic corresponding to the on-resistance Ron”, corresponds to a “first MOS transistor”.

### <Measuring System 1>

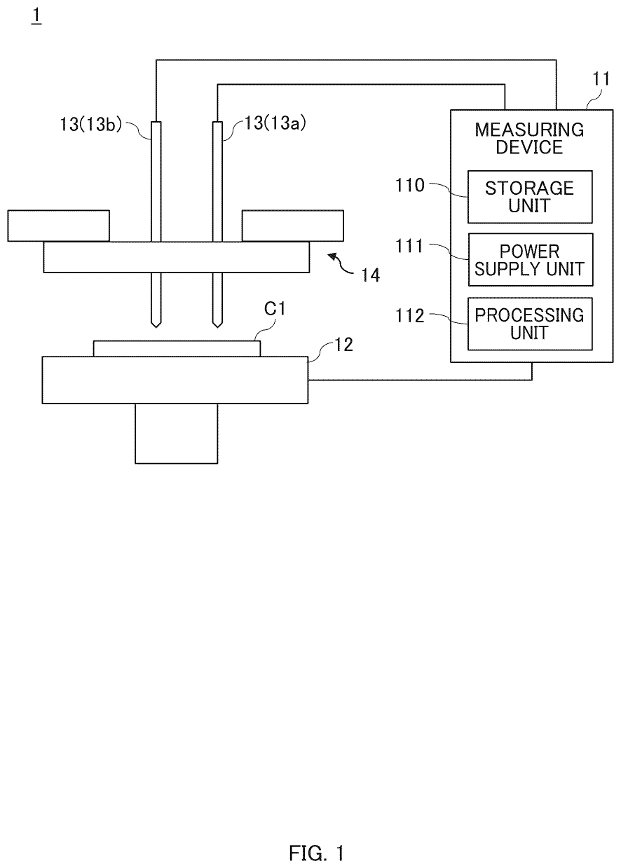

FIG. 1 is a diagram illustrating a measuring system 1 that performs a measuring method according to an embodiment of the present disclosure. The measuring system 1 is a system to measure the on-voltage Von. The measuring system 1 is the system to further perform measurements to obtain a in correlation CR1 (described later in detail) used measuring the on-voltage Von.

The measuring system 1 includes a measuring device 11, a stage 12, and a contact probe 13.

### [Measuring Device 11]

The measuring device 11 is a device to measure the characteristics of the MOS transistor T1 (described later) formed at a semiconductor chip C1. The measuring device 11 includes a storage unit 110, a power supply unit 111, and a processing unit 112.

The storage unit 110 includes, for example, a Random-Access Memory (RAM) and the like, and temporarily stores various programs, data, and the like. The storage unit 110 further includes a hard disk, and stores various data to be processed by the processing unit 112 (described later).

The storage unit 110 stores information about the semiconductor chip C1 (such as chip size, electrode layout, etc.), programs for executing tests, and the like. Further, the storage unit 110 also stores a measurement result of each semiconductor chip C1.

The power supply unit 111 is a device that includes a voltage source, and supplies a power supply voltage to be used for various measurements in the measuring method according to an embodiment of the present disclosure. Specifically, the power supply unit 111 applies the voltage between the stage 12 and the contact probe 13 (described later).

The power supply unit 111 may also include a current source to measure the voltage between various electrodes, in the state in which a predetermined current is supplied to the MOS transistor T1.

The processing unit 112 is a CPU, and executes a program stored in the storage unit 110, for example, and performs a measurement for each semiconductor chip C1 while controlling the stage 12, the contact probe 13, and the like (described later).

### [Stage 12]

The stage 12 is a metal stage at which the semiconductor chip C1 is to be placed during the measurement, and is connected to the measuring device 11. The semiconductor chip C1 is placed at the stage 12 in an aligned state.

It is assumed, in an embodiment of the present disclosure, that the measurement is performed for each semiconductor chip C1, but the measurement may be performed for the semiconductor chips C1 in the state before being separated from a wafer by dicing.

Further, the stage 12 performs vacuum-suction onto the semiconductor chip C1. This secures the semiconductor chip C1 onto the stage 12, and electrically connects the back surface of the semiconductor chip C1 (the drain electrode DE of the semiconductor chip C) to the stage 12.

The stage 12 moves vertically, to cause the contact probes 13a and 13b to contact the electrodes of the semiconductor chip C1 such that they are electrically connected.

### [Contact Probe 13]

The contact probe 13 is a member to cause its tip to contact the electrode at the front surface of f the semiconductor chip C1, to thereby perform the measurement.

The measuring system 1 according to an embodiment of the present disclosure has two contact probes 13a and 13b. The contact probes 13a and 13b are connected to the measuring device 11 and fixed to a mounting base 14.

During the measurement, the contact probes 13a and 13b respectively contact a gate electrode GE and a source electrode SE of the semiconductor chip C1.

### <Semiconductor Chip C1>

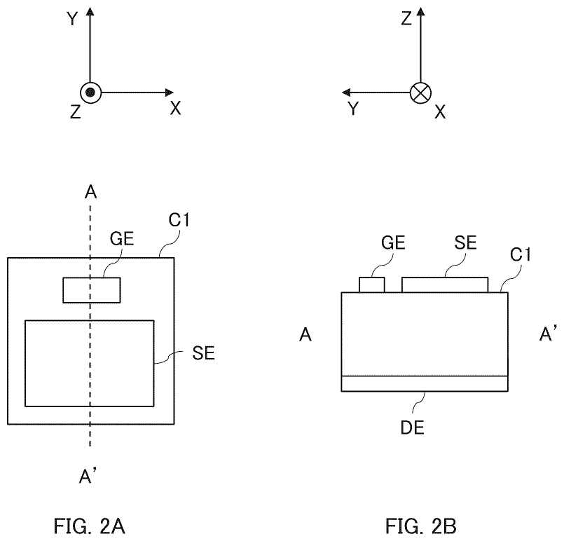

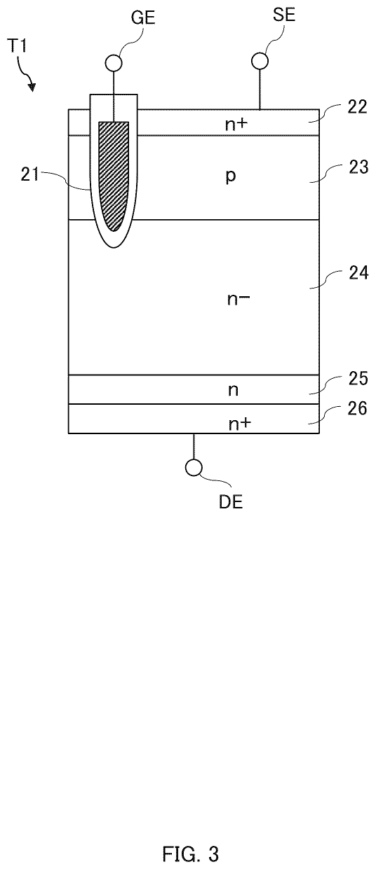

FIGS. 2 and 3 are diagrams for explaining the semiconductor chip C1 where the MOS transistor T1, which is to be measured by the measuring method according to an embodiment of the present disclosure, is formed.

The semiconductor chip C1 has a front surface and a back surface on a side opposite to the side of the front surface. At the semiconductor chip C1, an n-channel MOS transistor (hereinafter simply referred to as “MOS transistor”) is formed.

In the following, three directions that intersect one another with respect to the semiconductor chip C1 during the measurement are specifically defined. The direction extending along the lateral direction of the paper of FIG. 2 is defined as an X direction, and the direction extending along the vertical direction of the paper is defined as a Y direction.

Further, the direction that intersects the X and Y directions (the thickness direction of the semiconductor chip C1) is defined as a Z direction (also referred to as up-down direction), wherein the front surface side of the semiconductor chip C1 is defined as “up”, and the back surface side thereof is defined as “down” (see FIG. 2).

FIG. 2A illustrates a top view and FIG. 2B illustrates a cross-sectional view of the semiconductor chip C1. The semiconductor chip C1 is rectangular in top view in an embodiment of the present disclosure, and has the gate electrode GE, the source electrode SE, and the drain electrode DE.

The drain electrode DE is configured with (formed of) a metal film at the back surface (lower surface) of the semiconductor chip C1. Thus, in response to the semiconductor chip C1 is placed at the metal stage 12, the drain electrode DE is electrically connected to the stage 12.

The gate electrode GE and the source electrode SE are formed so as to be exposed at the front surface (upper surface) of the semiconductor chip C1. During the measurement, usually, a plurality of contact probes 13 are caused to contact the source electrode SE, but in an embodiment of the present disclosure, the contact probes 13a and 13b are caused to contact the gate electrode GE and the source electrode SE, respectively, for simplicity.

FIG. 3 illustrates a cross section of the MOS transistor T1 formed at the semiconductor chip C1. The MOS transistor T1 has a gate insulating film 21, an n+ region 22, a p region 23, an n-region 24, an n region 25, and an n+ region 26.

Here, the n-region 24 in particular is a so-called drift region. As will be described later, the lower the impurity concentration in the n-region 24, the higher the withstand voltage of the MOS transistor T1. Further, the thicker the n-region 24, the higher the withstand voltage of the MOS transistor T1.

Furthermore, the p region 23 is a so-called channel region. As will be described later, the higher the impurity concentration in the p region 23, the more a threshold voltage Vth of the MOS transistor T1 shifts in the positive direction.

### <Correlation CR1>

As described above, in an embodiment of the present disclosure, the correlation CR1 (corresponding to a “first correlation” in an embodiment of the present disclosure) is used in measuring the on-voltage Von. Here, the “correlation CR1” refers to the relationship between the characteristic corresponding to the on-resistance of each of a plurality of MOS transistors T2 and a withstand voltage Vdss of each of the plurality of MOS transistors T2.

Here, the plurality of MOS transistors T2 are MOS transistors that are used to obtain the correlation CR1 and are different from the MOS transistor T1 that is to be measured by the measuring method according to an embodiment of the present disclosure.

Each of the MOS transistors T2 is formed at a semiconductor chip C2. The semiconductor chip C2 has the same configuration as that of the semiconductor chip C1 described with reference to FIGS. 2 and 3, and thus a description thereof is omitted.

Note that the MOS transistor T2 used for the measurement to obtain the correlation CR1 corresponds to a “second MOS transistor”.

Further, the “withstand voltage Vdss” refers to the drain-source voltage when a predetermined current Idss flows while a predetermined voltage smaller than the threshold voltage Vth is applied between the gate and the source of the MOS transistor.

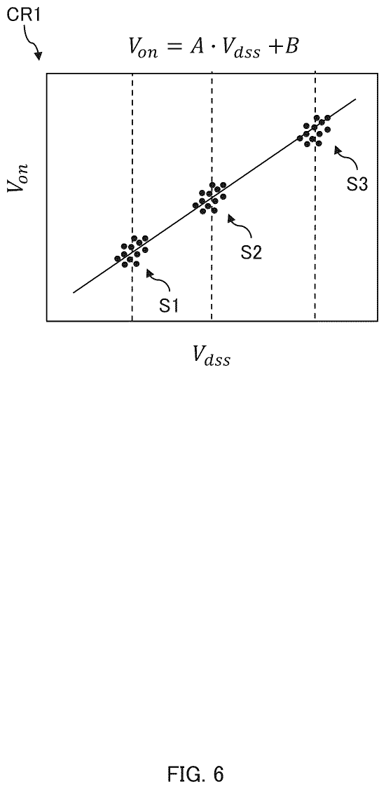

First, a description will be given of the measuring method of each of the on-voltage Von and the withstand voltage Vdss to obtain the correlation CR1 in FIG. 6.

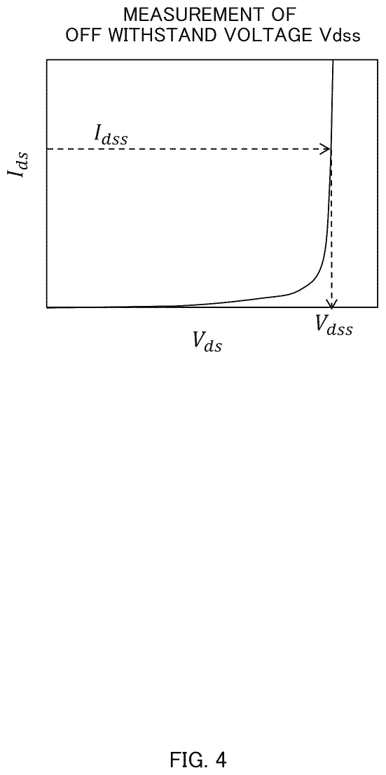

FIG. 4 is a diagram illustrating a method of measuring the withstand voltage Vdss. FIG. 4 illustrates the results of measurements of the characteristics of the MOS transistor T2 when being off, where the horizontal axis represents a drain-source voltage Vds and the vertical axis represents a drain current Ids.

In the measurement of the withstand voltage Vdss illustrated in FIG. 4, the predetermined voltage Vgs smaller than the threshold voltage Vth is applied between the gate and the source of the MOS transistor T2. In this state, the drain current Ids is measured while the voltage Vds applied between the drain and the source is increased from 0 V.

In this measurement, when the voltage Vds is increased from 0 V, the drain current Ids is very weak. When the voltage Vds is further increased, avalanche breakdown occurs in the MOS transistor T2, and the drain current Ids increases rapidly.

The withstand voltage Vdss is the drain-source voltage Vds when avalanche breakdown occurs in the MOS transistor T2. In an embodiment of the present disclosure, as illustrated in FIG. 4, the drain-source voltage Vds when the constant current Idss flows between the gate and the source of the MOS transistor T2 is defined as the withstand voltage Vdss.

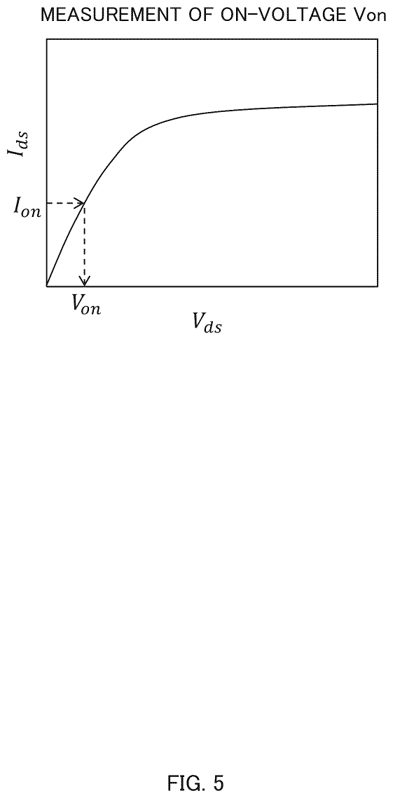

FIG. 5 is a diagram for explaining a method of measuring the on-voltage Von. FIG. 5 illustrates the results of measurements of the on-voltage Von of the MOS transistor T2, where the horizontal axis represents the drain-source voltage Vds and the vertical axis represents the drain current Ids.

In the measurements of the on-voltage Von illustrated in FIG. 5, the predetermined voltage Vgs larger than the threshold voltage Vth is applied between the gate and the source of the MOS transistor T2. In this state, the drain current Ids is measured while the voltage Vds applied between the drain and the source is increased from 0 V.

In this measurement, when the voltage Vds is in the vicinity of 0 V, the drain current Ids changes substantially linearly. When the voltage Vds is further increased, the drain current Ids transitions from a linear region to a saturation region, and remains substantially constant.

In an embodiment of the present disclosure, as illustrated in FIG. 5, the drain-source voltage Vds when the constant current Ion flows between the gate and the source of the MOS transistor T2 is defined as the on-voltage Von.

Here, the constant current Ion is the current value in a linear region, and is the current value determined assuming the state of actual use.

FIG. 6 is a diagram illustrating the correlation CR1 used in a measuring method in an embodiment of the present disclosure. This figure, where the horizontal axis is the withstand voltage Vdss and the vertical axis is the on-voltage Von, illustrates a scatter plot of the withstand voltage Vdss and the on-voltage Von obtained from respective measurements of the plurality of MOS transistors T2.

This example illustrates a scatter plot obtained from measurements of the MOS transistors T2 of three types of specifications S1 to S3 in which the withstand voltages Vdss is different in specification from one another.

The specifications S1 to S3 differ from one another in the configuration of the MOS transistor (FIG. 3), such as the thickness of the n-region 24 and the impurity concentration in the n-region 24. In other words, to obtain the correlation CR1, the plurality of MOS transistors T2 with different configurations as such are used.

As can be seen from FIG. 6, a linear correlation is observed between the withstand voltage Vdss and the on-voltage Von. FIG. 6 illustrates a graph of a linear function obtained from this scatter plot.

Further, the on-voltage Von can be given by the following expression:

$$Von = A \cdot Vdss + B , \qquad ( Expression 1 )$$

where A is the slope of the linear function extracted from the scatter plot and B is the intercept.

### <Measurement Condition in Obtaining Correlation CR1>

The correlation CR1 illustrated in FIG. 6 may be obtained using as many measurement results of the MOS transistors T2 as possible.

The correlation CR1 may be a relationship derived from the measurement results of the on-voltage Von and the withstand voltage Vdss with respect to each of at least 30 of the MOS transistors T2.

In this example, the total number of the MOS transistors T2 of the specifications S1 to S3 may be at least 30.

Further, in this example, the number of the MOS transistors T2 of each of the specifications S1 to S3 may be at least 10.

Furthermore, the correlation CR1 may be a relationship obtained from the measurement results of the on-voltage Von and the withstand voltage Vdss with respect to each of the MOS transistors T2 of a plurality of different specifications where the withstand voltages are different in specification from one another.

In this case, the number of the MOS transistors T2 for each of the specifications may be at least 30.

Further, the correlation CR1 is a relationship obtained when the on-voltage Von is measured under the condition that the contact resistance Rc between the stage 12 at which the MOS transistor T2 is to be placed and the electrode of the MOS transistor is equal to or less than a predetermined rate of the on-resistance of the MOS transistor T2.

The on-voltage Von measured in this event may be a value obtained under the condition that the contact resistance Rc is 1% or less of the on-resistance Ron of the MOS transistor T2.

Thus, the stage 12 that is as new as possible may be used. Accordingly, the stage 12 used to obtain the correlation CR1 may be restricted to the one from the time of shipment of the stage 12 to when a predetermined time period has elapsed since the shipment, for example.

### <Measurement Procedure>

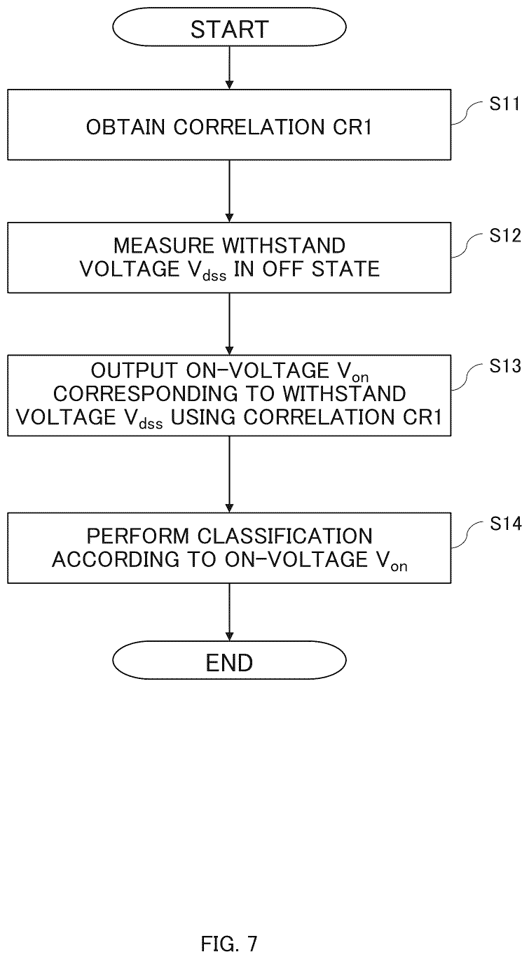

FIG. 7 is a flowchart for explaining a measuring method according to an embodiment of the present disclosure. The procedure of measuring the on-voltage Von of the MOS transistor T1 to be measured, will be described with reference to FIG. 7.

First, in step S11, the processing unit 112 of the measuring device 11 obtains the correlation CR1 previously prepared. In an embodiment of the present disclosure, Expression 1 (the expression of the linear function illustrated in FIG. 6) is obtained.

In this event, the processing unit 112 obtains the correlation CR1 from the storage unit 110 of the measuring device 11 (FIG. 1). Alternatively, when the correlation CR1 is stored in a storage unit of another device of the measuring device 11, the correlation CR1 is obtained from the storage unit of the device in which the correlation CR1 is stored.

Next, in step S12, the processing unit 112 measures the withstand voltage Vdss of the MOS transistor T1. The method of measuring the withstand voltage Vdss is the same as the method of measuring the withstand voltage Vdss of the MOS transistor T2 explained with reference to FIG. 4.

Next, in step S13, the processing unit 112 outputs the on-voltage Von of the MOS transistor T1 using the correlation CR1 and the withstand voltage Vdss of the MOS transistor T1 measured in step S12.

Specifically, the on-voltage Von on the left side obtained by substituting the withstand voltage Vdss of the MOS transistor T1 measured in step S12 into the right side of Expression 1, is outputted.

Finally, in step S14, the processing unit 112 classifies the MOS transistor T1 into any one of a plurality of groups, based on the on-voltage Von of the MOS transistor T1 outputted in step S13.

Here, the term “a plurality of groups” refers to groups obtained by dividing a predetermined range that includes the on-voltage Von (details thereof will be described later).

Further, the phrase “classifying the MOS transistor T1 into any one of the groups” refers to, in an embodiment of the present disclosure, the following process executed by the processing unit 112 of the measuring device 11.

First, the processing unit 112 gives an identification number of the group corresponding to the on-voltage Von of the MOS transistor T1, to the semiconductor chip C1 at which the MOS transistor T1 is formed.

Next, the processing unit 112 stores, in the storage unit 110 of the measuring device 11, data linking the identification number attached to the semiconductor chip C1 and the identification number of the group corresponding to the on-voltage Von of the MOS transistor T1 formed at the semiconductor chip C1.

The above process corresponds to the process of “classifying the MOS transistor T1 into any one of the groups”.

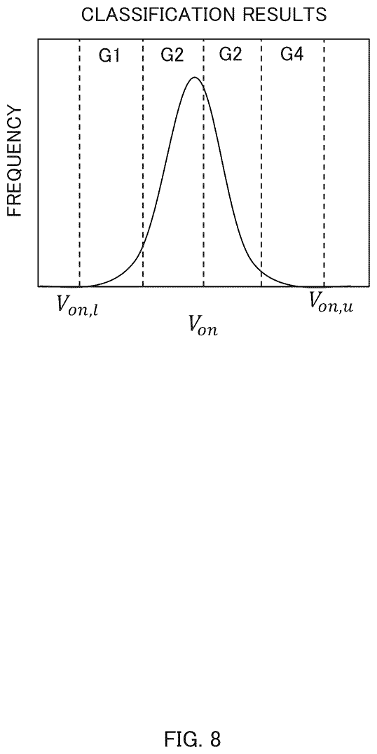

FIG. 8 is a diagram for explaining the classification results for a plurality of MOS transistors T1. In this figure, the horizontal axis represents the outputted on-voltage Von, and the vertical axis represents a histogram illustrating the frequency with respect to the voltage Von.

In this example, the range between a predetermined lower limit value Von, 1 and a predetermined upper limit value Von, u is set as the range including the on-voltage Von. Then, this range is divided into four equal parts, thereby setting groups G1 to G4.

The lower limit value Von, 1 and the upper limit value Von, u are determined, based on assumed variations in the on-voltage Von, the allowable range capable of being used in actual products, and the like.

Further, in an embodiment of the present disclosure, the four groups G1 to G4 are set in the range between the lower limit value Von, 1 and the upper limit value Von, u, but the number of groups that are set may be two or more.

Note that after step S14, the MOS transistor T1 classified into any one of the groups in step S14 may be housed in a tray prepared for each of the groups.

The measuring method according to an embodiment of the present disclosure has been described above. In the measuring method according to an embodiment of the present disclosure, the on-voltage Von of the MOS transistor T1, which is the semiconductor device to be measured in the method of manufacturing the semiconductor device is not directly measured, but the withstand voltage Vdss is measured.

The measurement of the withstand voltage Vdss is performed in the state in which the MOS transistor T1 is off, and thus the drain current Ids that flows during the measurement is smaller than that in the measurement of the on-voltage Von. Accordingly, in the measurement of the withstand voltage Vdss, the influence of the contact resistance between the drain electrode DE and the stage 12 is also small.

Furthermore, the measurement of the on-voltage Von to obtain the correlation CR1 is performed under the condition that the contact resistance between the drain electrode DE and the stage 12 is sufficiently reduced, as described above.

Accordingly, by substituting the measured withstand voltage Vdss into Expression 1, which represents the correlation CR1, the on-voltage Von can be measured with high accuracy.

### <<Method of Manufacturing Semiconductor Module 3>>

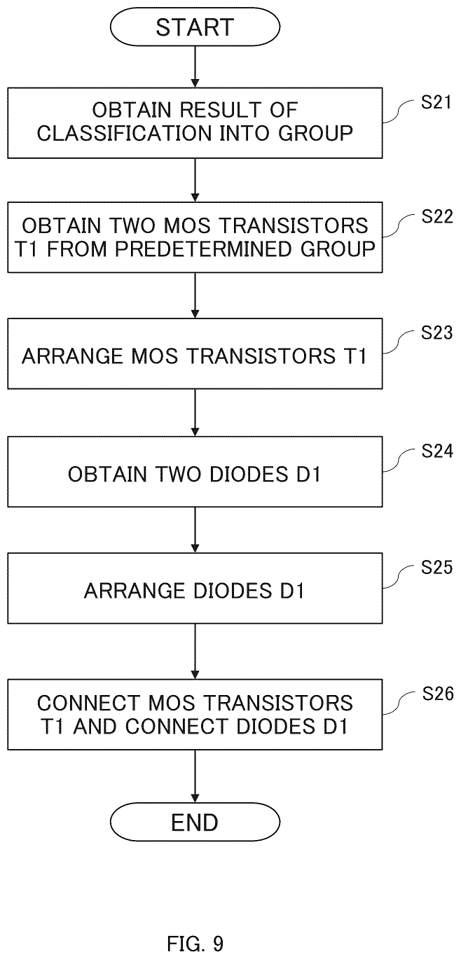

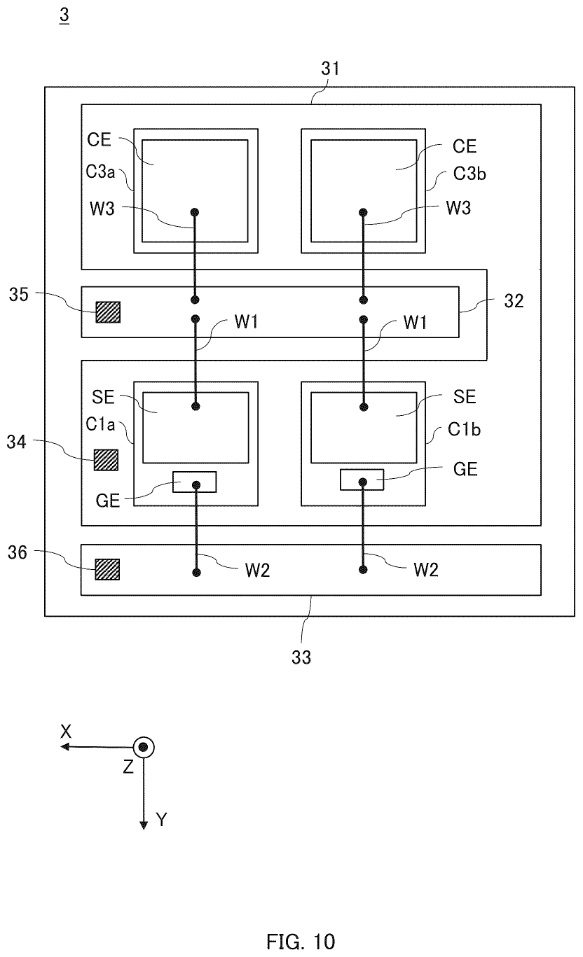

Next, a method of manufacturing a semiconductor module 3 that includes the MOS transistor T1 classified by the measuring method according to an embodiment of the present disclosure will be described with reference to FIGS. 9 and 10.

FIG. 9 is a flow chart illustrating a method of manufacturing the semiconductor module 3, which includes the MOS transistor T1 classified by the measuring method described above.

FIG. 10 is a plan schematic diagram for explaining the semiconductor module 3 manufactured by a manufacturing method according to an embodiment of the present disclosure. In this example, the semiconductor module 3 is a module in which the upper arm portion of a half bridge circuit for driving a load (not illustrated), such as a motor coil or the like, is mounted.

First, in step S21 of FIG. 9, a manufacturing device not illustrated obtains the classification result that has been obtained in the classification step (step S14 in FIG. 7) in the measuring method described above.

In this event, the manufacturing device obtains the classification result from the storage unit 110 (FIG. 1) of the measuring device 11. Alternatively, when the classification result is stored in a storage unit of another device of the measuring device 11, the classification result is obtained from the storage unit of the device in which the classification result is stored.

Next, in step S22, the manufacturing device uses the classification result obtained in step S21 to obtain two MOS transistors T1 included in a predetermined group among the plurality of groups.

In this case, when the predetermined group is, for example, the group G2 (FIG. 8), the manufacturing device obtains two MOS transistors T1 (the semiconductor chips C1a and C1b where the MOS transistors T1 are formed) from among the plurality of MOS transistors T1 classified into the group G2.

Next, in step S23, the manufacturing device arranges the two MOS transistors T1 (the semiconductor chips C1a and C1b) obtained in step S22 at the predetermined positions.

As a result, the semiconductor chips C1a and C1b are arranged on a conductive pattern 31 as illustrated in FIG. 10. In this event, each of the drain electrodes DE of the semiconductor chips C1a and C1b is connected to the conductive pattern 31. Note that the term “being connected” refers to being mechanically and electrically connected.

The conductive pattern 31 corresponds to wiring for electrically connecting the drain electrodes DE of the semiconductor chips C1a and C1b of the upper arm to a terminal 34 on the high potential side.

Next, in step S24, the manufacturing device obtains two diodes D1 (the semiconductor chips C3a and C3b where the diodes D1 are formed).

The diodes D1 are respectively formed at the semiconductor chips C3a and C3b, and in this example, the diodes D1 are Schottky barrier diodes.

Next, in step S25, the manufacturing device arranges the two diodes D1 (the semiconductor chips C3a and C3b) obtained in step S24 at the predetermined positions.

As a result, the semiconductor chips C3a and C3b are arranged on the conductive pattern 31 as illustrated in FIG. 10. In this event, each of the anode electrodes (not illustrated) of the semiconductor chips C3a and C3b is connected to the conductive pattern 31.

The conductive pattern 31 also corresponds to wiring to electrically connect the anode electrodes (not illustrated) formed at the back surfaces of the semiconductor chips C3a and C3b of the upper arm to the terminal 34 on the high potential side.

Next, in step S26, the manufacturing device connects the two MOS transistors T1 obtained in step S22 in parallel with each other, and connects the two diodes D1 obtained in step S24 in parallel with each other.

As a result, as illustrated in FIG. 10, the source electrode SE of each of the semiconductor chips C1a and C1b is connected to the conductive pattern 32 through a wire W1.

The conductive pattern 32 corresponds to wiring to electrically connect the source electrodes of the semiconductor chips C1a and C1b of the upper arm and the cathode electrodes CE of the semiconductor chips C3a and C3b of the upper arm to an output terminal 35.

Furthermore, as a result of step S26, the gate electrode GE of each of the semiconductor chips C1a and C1b is connected to the conductive pattern 33 through a wire W2.

The conductive pattern 33 corresponds to wiring to electrically connect the gate electrodes GE of the semiconductor chips C1a and C1b of the upper arm to a control terminal 36.

Furthermore, as a result of step S26, the cathode electrode CE of each of the semiconductor chips C3a and C3b is connected to the conductive pattern 32 through a wire W3.

The semiconductor module 3 (FIG. 10) can be manufactured by the manufacturing method described above. Note that the semiconductor chips C3a and C3b do not have to be included. In this case, the semiconductor chips and the conductive pattern 31 can be downsized. In the semiconductor module 3 according to an embodiment of the present disclosure manufactured by the method described above, the MOS transistors T1 respectively formed at the two semiconductor chips C1a and C1b are connected in parallel with each other.

The MOS transistors T1 respectively formed in these two semiconductor chips C1a and C1b are classified into the same group among the groups G1 to G4 illustrated in FIG. 8.

Thus, according to the semiconductor module 3 manufactured by the manufacturing method according to an embodiment of the present disclosure, it is possible to reduce the difference caused by the variations in the on-voltages Von of the MOS transistors T1 respectively formed at the two semiconductor chips C1a and C1b as compared to the case where the two semiconductor chips C1a and C1b are obtained from two different groups.

In other words, it is possible to reduce the difference between the on-resistances Ron of the two MOS transistors T1, in the case where a common voltage to turn on is applied between the gate and the source of each of the two MOS transistors T1.

This can cause the operation states of the two MOS transistors T1 to be substantially equal, and the heats respectively generated by the MOS transistors T1 to be substantially equal.

### Second Embodiment

A measuring method according to an embodiment of the present disclosure will be described. The measuring method according to an embodiment of the present disclosure is also a method of measuring a value corresponding to the on-resistance Ron. The measuring method according to an embodiment of the present disclosure uses a correlation different from that used in the measuring method of the first embodiment.

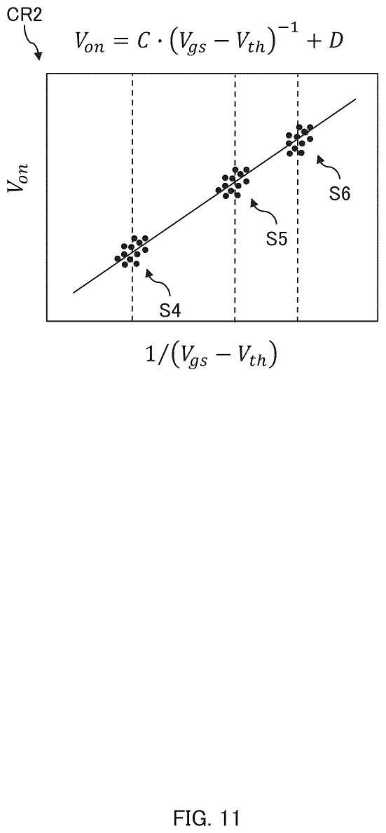

FIG. 11 is a diagram illustrating a correlation CR2 (corresponding to a “second correlation”) used in the measuring method according to an embodiment of the present disclosure. In this figure, the horizontal axis represents (Vgs−Vth)⁻¹ and the vertical axis represents the on-voltage Von. Here, Vgs is a predetermined voltage to be applied between the gate and the source when the on-voltage Von is measured (FIG. 5). Vth is a measurement value of the threshold voltage.

In other words, in an embodiment of the present disclosure, the correlation CR2 between the on-voltage Von and the withstand voltage Vth is used, instead of the correlation CR1 between the on-voltage Von and the threshold voltage Vdss in the first embodiment.

Further, a linear correlation is observed between the on-voltage Von and (Vgs−Vth)⁻¹, and thus, in FIG. 11, the horizontal axis is (Vgs−Vth)⁻¹ instead of the threshold voltage Vth.

This linear correlation is established because the resistance of the p region 23 (so-called channel region) illustrated in FIG. 3 is approximately proportional to (Vgs−Vth)⁻¹, when the voltage Vgs is applied between the gate and the source.

Further, the on-voltage Von can be given by the following expression by extracting the slope C and the intercept D of the linear function from the scatter plot in FIG. 11.

$$Von = C \cdot {( Vgs - Vth )}^{- 1} + D \qquad ( Expression 2 )$$

Note that this example illustrates a scatter plot obtained from the measurements of the MOS transistors T2 of three different specifications S4 to S6 in which the threshold voltages Vth are different in specification from one another.

The specifications S4 to S6 differ from one another in the configuration of the MOS transistor T2, such as the impurity concentration in the p region 23 (FIG. 3). That is, in order to obtain the correlation CR2, the plurality of MOS transistors T2 with different configurations as such are used in an embodiment of the present disclosure.

Next, a method of measuring the on-voltage Von of the MOS transistor T1 to be measured will be described. The following describes differences between the first embodiment and the second embodiment, and common features are omitted.

The measuring method according to an embodiment of the present disclosure obtains the expression of the linear function given by Expression 2, instead of step S11 of the first embodiment illustrated in FIG. 7.

Next, the threshold voltage Vth of the MOS transistor T1 to be measured is measured, instead of step S12 of the first embodiment illustrated in FIG. 7.

Next, the on-voltage Von of the MOS transistor T1 is outputted using the above-mentioned correlation CR2 and the measured threshold voltage Vth of the MOS transistor T1, instead of step S13 of the first embodiment illustrated in FIG. 7.

Finally, the MOS transistor T1 is classified into any one of the plurality of groups by the same procedure as in step S14 of the first embodiment illustrated in FIG. 7. Here, the plurality of groups refers to groups that are set in the same procedure as in the first embodiment.

With the use of the correlation CR2 as such, it is possible to measure the on-voltage Von of the MOS transistor T1 with high accuracy.

### SUMMARY

The measuring method in the first embodiment described above is a method of manufacturing a semiconductor device including: measuring the withstand voltage Vdss of the MOS transistor T1, which is the semiconductor device, when being off; and outputting the characteristic of the MOS transistor T1, using the correlation CR1 between the characteristic corresponding to the on-resistance Ron of each of the plurality of MOS transistors T2 and the withstand voltage Vdss of each the plurality of MOS transistors T2, and the measured withstand voltage Vdss of the MOS transistor T1, wherein the correlation CR1 is a relationship obtained when the characteristic corresponding to the on-resistance Ron is measured under the condition that the contact resistance between the stage 12 at which the MOS transistor T2 is to be placed and the electrode of the MOS transistor T2 is equal to or lower than the predetermined rate of the on-resistance Ron of the MOS transistor T2.

According to such a measuring method, the withstand voltage Vdss is measured, without the need for directly measuring the characteristic corresponding to the on-resistance Ron of the MOS transistor T1 to be measured. The measurement of the withstand voltage Vdss is performed in the state where the MOS transistor T1 is off, and thus the drain current Ids flowing during the measurement is smaller than that in the measurement of the characteristic corresponding to the on-resistance Ron. This makes it possible to reduce the influence of the contact resistance Rc between the stage 12 and the drain electrode DE during the measurement. Furthermore, the measurement of the on-voltage Von to obtain the correlation CR1 is performed under the condition that the contact resistance Rc between the drain electrode DE and the stage 12 is reduced. Accordingly, the characteristic corresponding to the on-resistance Ron is measured with high accuracy.

In the measuring method according to an embodiment, the correlation CR1 is a relationship obtained from measurement results of the withstand voltage Vdss and the characteristic corresponding to the on-resistance Ron of each of at least 30 of the MOS transistors T2. According to such a method, the accuracy of the correlation CR1 is improved, thereby improving the accuracy of the measurement of the characteristic corresponding to the on-resistance Ron.

In the measuring method according to an embodiment, the characteristic corresponding to the on-resistance Ron is a value obtained under the condition that the contact resistance Rc is 1% or less of the on-resistance of the second MOS transistor T2. According to such a method, the accuracy of the correlation CR1 is improved, thereby improving the accuracy of the measurement of the characteristic corresponding to the on-resistance Ron.

In the measuring method according to an embodiment, the characteristic corresponding to the on-resistance Ron is the drain-source voltage Vds (on-voltage Von) when the constant current Ion flows, while the predetermined voltage Vgs is being applied between the gate and the source of the MOS transistor T1 to be measured. According to this method, the on-voltage Von can be measured with high accuracy.

In the measurement method according to an embodiment further includes classifying the MOS transistor T1 into one of the plurality of groups that are obtained by dividing the predetermined range including the characteristic corresponding to the on-resistance Ron, based on the characteristic of the MOS transistor T1. According to such a measuring method, it is possible to measure the on-voltage Von with high accuracy as described above, thereby improving the accuracy of classification into each one of the groups.

Further, the method of manufacturing the semiconductor module 3 according to an embodiment is a method of manufacturing the semiconductor module 3 that includes the MOS transistor T1 classified by the measuring method according to an embodiment, the method including obtaining two MOS transistors T1 included in the predetermined group of the plurality of groups, the two MOS transistors T1 each being the MOS transistor T1; and connecting the obtained two MOS transistors T1 in parallel with each other. According to such a method, the operation states of the two MOS transistors T1 connected in parallel with each other can be made substantially equal, and the heats generated by the two can be made substantially equal.

Further, in the measuring method according to a second embodiment is a method of manufacturing a semiconductor device, the method including: measuring the threshold voltage Vth of the MOS transistor T1, which is the semiconductor device; and outputting the characteristic of the MOS transistor T1, using the correlation CR2 between the characteristic corresponding to the on-resistance Ron of each of the plurality of MOS transistors T2 and the threshold voltage of each the plurality of the MOS transistors T2, and the measured threshold voltage Vth of the MOS transistor T1, wherein the correlation CR2 is a relationship obtained when the characteristic is measured under the condition that the contact resistance between the stage 12 at which the MOS transistor T2 is to be placed and the electrode of the MOS transistor T2 is equal to or lower than the predetermined rate of the on-resistance Ron of the MOS transistor T2.

According to such a measuring method, the threshold voltage Vth is measured, without directly measuring the characteristic corresponding to the on-resistance Ron of the MOS transistor T1 to be measured. The drain current Ids flowing during the measurement in the state in which the threshold voltage Vth is applied between the source and the gate of the MOS transistor T1, is smaller than that in the measurement of the characteristic corresponding to the on-resistance Ron. This makes it possible to reduce the influence of the contact resistance Rc between the stage 12 and the drain electrode DE during the measurement. Furthermore, the measurement of the on-voltage Von to obtain the correlation CR2 is performed under the condition that the contact resistance Rc between the stage 12 and the drain electrode DE is reduced. Accordingly, the characteristic corresponding to the on-resistance Ron is measured with high accuracy.

The present disclosure is directed to provision of a measuring method and a manufacturing method capable of measuring the characteristic corresponding to the on-resistance of a MOS transistor with high accuracy.

According to the present disclosure, it is possible to provide a measuring method and a manufacturing method capable of measuring the characteristic corresponding to the on-resistance of a MOS transistor with high accuracy.

What is claimed is:

1. A method of measuring a characteristic of a semiconductor device that is a first metal-oxide-semiconductor (MOS) transistor using a stage, the method comprising:
obtaining a first correlation between a characteristic, and a withstand voltage, each of a plurality of second MOS transistors, the characteristic being measured under a condition that a contact resistance between the stage, at which said each second MOS transistor is placed, and an electrode of said each second MOS transistor, is equal to or lower than a predetermined rate of an on-resistance of said each second MOS transistor;
measuring a withstand voltage of the first MOS transistor when the first MOS transistor is off; and
outputting the characteristic of the first MOS transistor, using the first correlation and the measured withstand voltage of the first MOS transistor.

2. The method of measuring the semiconductor device according to claim 1, wherein the plurality of second MOS transistors includes at least 30 second MOS transistors.

3. The method of measuring the semiconductor device according to claim 1, wherein the contact resistance is 1% or less of the on-resistance of said each second MOS transistor.

4. The method of measuring the semiconductor device according to claim 1, wherein the characteristic of the first MOS transistor and the characteristic of each of the plurality of second MOS transistors are each a drain-source voltage when a predetermined current flows, while a predetermined voltage is being applied between a gate and a source of the first MOS transistor or said each second MOS transistor.

5. The method of measuring the semiconductor device according to claim 1, the method further comprising:
classifying the first MOS transistor into one of a plurality of groups that are obtained by dividing a predetermined range of the characteristic thereof, based on the outputted characteristic of the first MOS transistor.

6. A method of manufacturing a semiconductor device, comprising the method of measuring the semiconductor device according to claim 5.

7. A method of manufacturing a semiconductor module, comprising:
obtaining two first MOS transistors included in a predetermined group of a plurality of groups, each of the two first MOS transistors being classified into the predetermined group using the method of measuring the semiconductor device according to claim 5; and
connecting the obtained two first MOS transistors in parallel with each other.

8. A method of measuring a characteristic of a semiconductor device that is a first metal-oxide-semiconductor (MOS) transistor using a stage, the method comprising:
obtaining a correlation between a characteristic, and a threshold voltage, of each of a plurality of second MOS transistors, the characteristic being measured under a condition that a contact resistance between the stage, at which said each second MOS transistor is placed, and an electrode of said each second MOS transistor, is equal to or lower than a predetermined rate of an on-resistance of said each second MOS transistor;
measuring a threshold voltage of the first MOS transistor; and
outputting the characteristic of the first MOS transistor, using the obtained correlation and the measured threshold voltage of the first MOS transistor.
